(19) United States
(12) Patent Application Publication
(10) Pub. No.: US 2024/0213078 A1
(43) Pub. Date: Jun. 27, 2024

(54) SUBSTRATE SUPPORTS AND TRANSFER APPARATUS FOR SUBSTRATE DEFORMATION

(71) Applicant: Applied Materials, Inc., Santa Clara, CA (US)

(72) Inventors: Zhepeng CONG, San Jose, CA (US); Xinning LUAN, Tempe, AZ (US)

(21) Appl. No.: 18/087,255

(22) Filed: Dec. 22, 2022

(51) Int. Cl. H01L 21/687; F27B 17/00; F27D 5/00; H01L 21/67

(52) U.S. Cl. CPC H01L 21/6875; F27B 17/0025; F27D 5/0037; H01L 21/67115; H05B 3/0047

(57) ABSTRACT

Embodiments of the present disclosure relate to substrate supports, transfer apparatus, processing chambers, and related components and methods, for substrate deformation (e.g., bowing). In one or more implementations, a substrate used in relation to the present disclosure can be deformed (e.g., bowed) before and/or during processing (such as epitaxial deposition). In one implementation, a substrate support applicable for use in semiconductor manufacturing operations includes a support body. The support body includes an outer surface, a recessed surface that is recessed relative to the outer surface, and a pocket surface between the outer surface and the recessed surface. The recessed surface and the pocket surface at least partially define a pocket of the support body. The support body includes a plurality of supports protruding relative to the recessed surface. The substrate support includes a barrier interfacing with the plurality of supports. The barrier includes a plurality of barrier supports.

### BACKGROUND

### Field

Embodiments of the present disclosure relate to substrate supports, transfer apparatus, processing chambers, and related components and methods, for substrate deformation (e.g., bowing). In one or more implementations, a substrate used in relation to the present disclosure can be deformed (e.g., bowed) before and/or during processing (such as epitaxial deposition).

### Description of the Related Art

Semiconductor substrates are processed for a wide variety of applications, including the fabrication of integrated devices and microdevices. Substrates can become deformed (e.g., bowed), and the deformation can cause temperature non-uniformities throughout processing, which can cause deposition non-uniformities. As an example, the deformation can change the amount of surface area(s) of the substrates that contact other components. As another example, as another example, the deformation can change the distance(s) of portion(s) of the substrates relative to other components. Such issues can be exacerbated by relatively complex deposition operations (such as high-temperature epitaxial deposition operations).

Therefore, a need exists for improved substrate supports, transfer apparatus, processing chambers, and related components and methods that account for deformations and facilitate reduced deposition non-uniformities.

### SUMMARY

Embodiments of the present disclosure relate to substrate supports, transfer apparatus, processing chambers, and related components and methods, for substrate deformation (e.g., bowing). In one or more implementations, a substrate used in relation to the present disclosure can be deformed (e.g., bowed) before and/or during processing (such as epitaxial deposition).

In one implementation, a substrate support applicable for use in semiconductor manufacturing operations includes a support body. The support body includes an outer surface, a recessed surface that is recessed relative to the outer surface, and a pocket surface between the outer surface and the recessed surface. The recessed surface and the pocket surface at least partially define a pocket of the support body. The support body includes a plurality of supports protruding relative to the recessed surface. The substrate support includes a barrier interfacing with the plurality of supports. The barrier includes a plurality of barrier supports.

In one implementation, a processing chamber applicable for use in semiconductor manufacturing includes a window at least partially defining a processing volume, a plurality of heat sources configured to heat the processing volume, and a substrate support disposed in the processing volume. The substrate support includes a support body. The support body includes an outer surface, a recessed surface that is recessed relative to the outer surface, a pocket surface between the outer surface and the recessed surface, and a plurality of supports protruding relative to the recessed surface. The substrate support includes a barrier interfacing with the plurality of supports. The barrier includes a plurality of barrier supports.

In one implementation, a transfer apparatus for moving a substrate in relation to semiconductor manufacturing includes a transfer body. The transfer body includes an outer surface, an arcuate recessed surface that is recessed relative to the outer surface, and a pocket surface between the outer surface and the arcuate recessed surface.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, may admit to other equally effective embodiments.

FIG. 1 is a schematic side cross-sectional view of a processing chamber, according to one implementation.

FIG. 2 is a schematic side cross-sectional view of the substrate support shown in FIG. 1, according to one implementation.

FIG. 3 is a schematic side view of the barrier shown in FIG. 2, according to one implementation.

FIG. 4 is a schematic top view of the barrier shown in FIGS. 2-3, according to one implementation.

FIG. 5 is a schematic bottom view of the barrier shown in FIGS. 2-4, according to one implementation.

FIG. 6 is a schematic top view of the support body shown in FIG. 2, according to one implementation.

FIG. 7 is a schematic side cross-sectional view of a substrate support, according to one implementation.

FIG. 8 is a schematic perspective view of a transfer apparatus, according to one implementation.

FIG. 9 is a schematic side cross-sectional view of the transfer apparatus shown in FIG. 8, according to one implementation.

FIG. 10 is a schematic side cross-sectional view of a transfer apparatus, according to one implementation.

FIG. 11 is a schematic block diagram view of a method of processing a substrate for semiconductor manufacturing, according to one implementation.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure relate to substrate supports, transfer apparatus, processing chambers, and related components and methods, for substrate deformation (e.g., bowing). In one or more implementations, a substrate used in relation to the present disclosure can be deformed (e.g., bowed) before and/or during processing (such as epitaxial deposition).

Deformations can be involved, for example, in relation to three-dimensional dynamic random access memory (3D DRAM) deposition operations or epitaxial deposition operations that deposit relatively thick films which can induce stains.

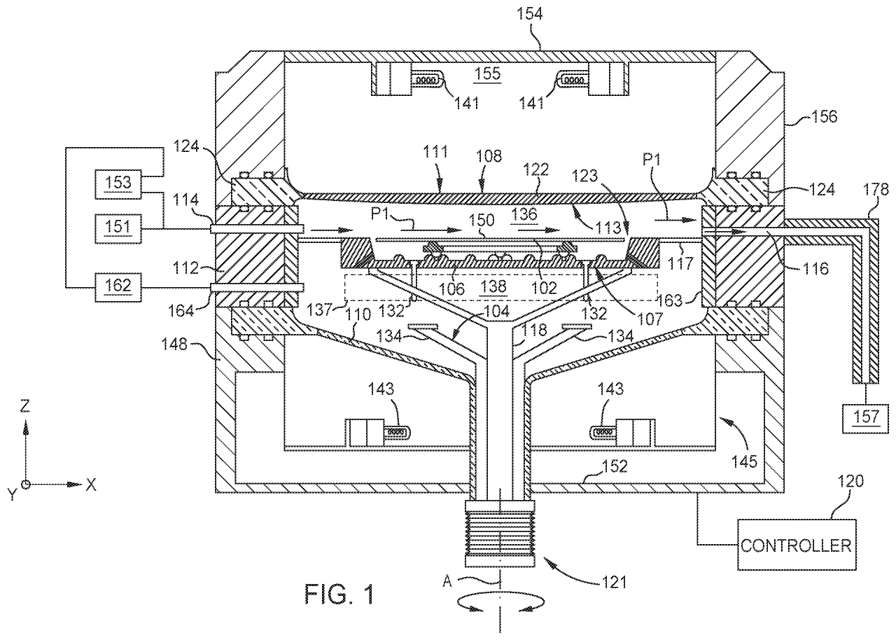

FIG. 1 is a schematic side cross-sectional view of a processing chamber 100, according to one implementation. The processing chamber 100 is a deposition chamber. In one embodiment, which can be combined with other embodiments, the processing chamber 100 is an epitaxial deposition chamber. The processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, and a flow module 112 disposed between the upper body 156 and the lower body 148. The upper body 156, the flow module 112, and the lower body 148 form a chamber body. Disposed within the chamber body is a substrate support 106, an upper window 108 (such as an upper dome), a lower window 110 (such as a lower dome), a plurality of upper heat sources 141, and a plurality of lower heat sources 143. As shown, a controller 120 is in communication with the processing chamber 100 and is used to control processes and methods, such as the operations of the methods described herein. The controller 120 and the processing chamber 100 can be part of a substrate processing system.

In the implementation shown in FIG. 1, the heat sources 141, 143 are lamps. Other heat sources are contemplated, such as resistive heaters, light emitting diodes (LEDs), and/or lasers.

The substrate support 106 is disposed between the upper window 108 and the lower window 110. The substrate support 106 includes a support face 123 that supports the substrate 102. The plurality of upper heat sources 141 are disposed between the upper window 108 and a lid 154. The plurality of upper heat sources 141 form a portion of the upper heating module 155. The lid 154 may include a plurality of sensors (such as pyrometers) disposed therein or thereon for measuring the temperature within the processing chamber 100. The plurality of lower heat sources 143 are disposed between the lower window 110 and a chamber floor 152. The plurality of lower heat sources 143 form a portion of a lower heating module 145. The upper window 108 is an upper dome and is formed at least partially of an energy transmissive material, such as quartz. The lower window 110 is a lower dome and is formed at least partially of an energy transmissive material, such as quartz.

A process volume 136 and a purge volume 138 are positioned between the upper window 108 and the lower window 110. The process volume 136 and the purge volume 138 are part of an internal volume defined at least partially by the upper window 108, the lower window 110, and the one or more liners 163. The upper window 108 at least partially defines the process volume 136.

The window 108 includes a first face 111 that is concave or flat (in the implementation shown in FIG. 1, the first face 111 is flat). The upper window 108 includes a second face 113 that is convex. The second face 113 faces the substrate support 106. The present disclosure contemplates other shapes for the upper window 108. The upper window 108 includes an inner section 122 and an outer section 124. The first face 111 and the second face 113 are at least part of the inner section 122. The inner section 122 is transparent and the outer section 124 is opaque. The outer section 124 is received at least partially in one or more sidewalls (such as in the flow module 112) of the processing chamber 100.

The internal volume has the substrate support 106 disposed therein. The substrate support 106 includes a top surface on which the substrate 102 is disposed. The substrate support 106 is connected to a shaft 118. In one or more embodiments, the substrate support 106 is connected to the shaft 118 through a plurality of arms 119 connected to the shaft 118. The shaft 118 is connected to a motion assembly 121. The motion assembly 121 includes one or more actuators and/or adjustment devices that provide movement and/or adjustment for the shaft 118 and/or the substrate support 106 within the processing volume 136.

The substrate support 106 may include lift pin holes 107 disposed therein. The lift pin holes 107 are sized to accommodate a lift pin 132 for lifting of the substrate 102 from the substrate support 106 either before or after a deposition process is performed. The lift pins 132 may rest on lift pin stops 134 when the substrate support 106 is lowered from a process position to a transfer position. The lift pin stops 134 can be coupled to a second shaft 104.

The flow module 112 includes a plurality of gas inlets 114, a plurality of purge gas inlets 164, and one or more gas exhaust outlets 116. The plurality of gas inlets 114 and the plurality of purge gas inlets 164 are disposed on the opposite side of the flow module 112 from the one or more gas exhaust outlets 116. One or more flow guides 117 are disposed below the plurality of gas inlets 114 and the one or more gas exhaust outlets 116. The one or more flow guides can include, for example, one or more pre-heat rings. The one or more flow guides 117 are disposed above the purge gas inlets 164. One or more liners 163 are disposed on an inner surface of the flow module 112 and protects the flow module 112 from reactive gases used during deposition operations and/or cleaning operations. The gas inlet(s) 114 and the purge gas inlet(s) 164 are each positioned to flow a gas parallel to the top surface 150 of a substrate 102 disposed within the process volume 136. The gas inlet(s) 114 are fluidly connected to one or more process gas sources 151 and one or more cleaning gas sources 153. The purge gas inlet(s) 164 are fluidly connected to one or more purge gas sources 162 and/or the one or more cleaning gas sources 153. The one or more gas exhaust outlets 116 are fluidly connected to an exhaust pump 157. One or more process gases supplied using the one or more process gas sources 151 can include one or more reactive gases (such as one or more of silicon (Si), phosphorus (P), and/or germanium (Ge)) and/or one or more carrier gases (such as one or more of nitrogen (N₂) and/or hydrogen (H₂)). One or more purge gases supplied using the one or more purge gas sources 162 can include one or more inert gases (such as one or more of argon (Ar), helium (He), hydrogen (H₂), and/or nitrogen (N₂)). One or more cleaning gases supplied using the one or more cleaning gas sources 153 can include one or more of hydrogen (H) and/or chlorine (Cl). In one embodiment, which can be combined with other embodiments, the one or more process gases include silicon phosphide (SiP) and/or phospine (PH₃), and the one or more cleaning gases include hydrochloric acid (HCl).

The one or more gas exhaust outlets 116 are further connected to or include an exhaust system 178. The exhaust system 178 fluidly connects the one or more gas exhaust outlets 116 and the exhaust pump 157. The exhaust system 178 can assist in the controlled deposition of a layer on the substrate 102. The exhaust system 178 is disposed on an opposite side of the processing chamber 100 relative to the flow module 112.

The controller 120 includes a central processing unit (CPU), a memory containing instructions, and support circuits for the CPU. The controller 120 controls various items directly, or via other computers and/or controllers. In one or more embodiments, the controller 120 is communicatively coupled to dedicated controllers, and the controller 120 functions as a central controller.

The controller 120 is of any form of a general-purpose computer processor that is used in an industrial setting for controlling various substrate processing chambers and equipment, and sub-processors thereon or therein. The memory, or non-transitory computer readable medium, is one or more of a readily available memory such as random access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)), read only memory (ROM), floppy disk, hard disk, flash drive, or any other form of digital storage, local or remote. The support circuits of the controller 120 are coupled to the CPU for supporting the CPU (a processor). The support circuits include cache, power supplies, clock circuits, input/output circuitry and subsystems, and the like. Operational parameters (such as a temperature of the substrate 102, a temperature of the substrate support 106, and/or a pressure and/or a temperature for process gas) and operations are stored in the memory as a software routine that is executed or invoked to turn the controller 120 into a specific purpose controller to control the operations of the various chambers/modules described herein. The controller 120 is configured to conduct any of the operations described herein. The instructions stored on the memory, when executed, cause one or more of operations of method 1100 (described below) to be conducted.

The various operations described herein (such as the operations of the method 1100) can be conducted automatically using the controller 120, or can be conducted automatically or manually with certain operations conducted by a user.

The controller 120 is configured to control the rotational position, the heating, and gas flow through the processing chamber 100 by providing an output to controls for the heat sources 141, 143, the gas flow, and the motion assembly 121. The controls include controls for the upper heat sources 141, the lower heat sources 143, the process gas source 151, the purge gas source 162, the motion assembly 121, and the exhaust pump 157.

The controller 120 is configured to adjust the output to the controls based off of sensor readings, a system model, and stored readings and calculations. The controller 120 includes embedded software and a compensation algorithm(s) to calibrate measurements. The controller 120 can include one or more machine learning algorithms and/or artificial intelligence algorithms that estimate optimized parameters for the deposition operations, the purge operations, and/or the cleaning operations. The one or more machine learning algorithms and/or artificial intelligence algorithms can use, for example, a regression model (such as a linear regression model) or a clustering technique to estimate optimized parameters. The algorithm can be unsupervised or supervised.

Substrates (such as the substrate 102) are transferred into and out of the internal volume of the processing chamber 100 through a transfer door 137 (such as a slit valve). When the transfer door 137 is open, a transfer apparatus (with a substrate supported thereon) can extend into the internal volume through the transfer door 137 such that the lift pins 132 can lift the substrate from the transfer apparatus and land the substrate on the substrate support 106 for processing. After processing, the lift pins 132 can lift the substrate from the substrate support 106 and land the substrate on a transfer apparatus, and the transfer apparatus can be retracted through the open transfer door 137 to remove the substrate from the processing chamber 100.

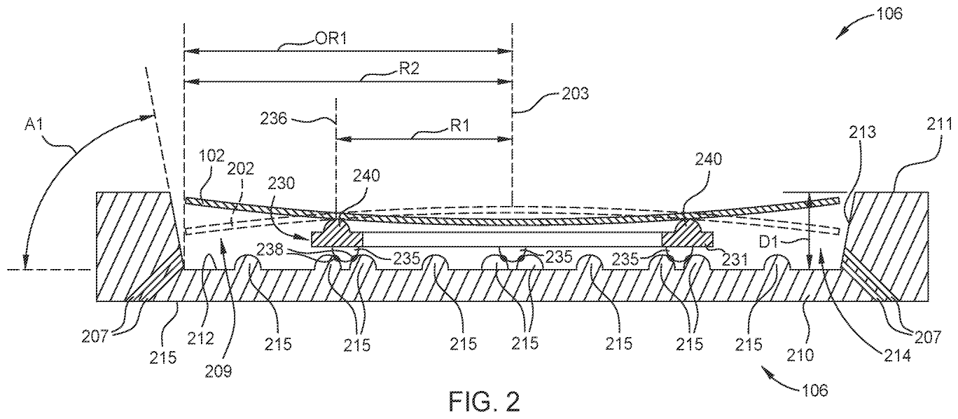

FIG. 2 is a schematic side cross-sectional view of the substrate support 106 shown in FIG. 1, according to one implementation.

The substrate support 106 includes a support body 210. In one or more embodiments, the support body 210 is part of a susceptor, such as a pedestal. The support body 210 includes an outer surface 211, a recessed surface 212 that is recessed relative to the outer surface 211, and a pocket surface 213. The pocket surface 213 is between the outer surface 211 and the recessed surface 212. The recessed surface 212 and the pocket surface 213 at least partially define a pocket 214 of the support body 210. The pocket has a cross-sectional shape that is trapezoidal. The substrate support 106 includes a plurality of supports 215 protruding relative to the recessed surface 212 and into the pocket 214. In one or more embodiments, each of the plurality of supports 215 is semi-ball shaped (such as semi-spherical in shape or semi-ovular in shape). A depth D1 of the pocket 214 is less than 1.0 mm. In one or more embodiments, the depth D1 is within a range of 0.7 mm to 0.8 mm. In one or more embodiments, the depth D1 is about 0.75 mm. The support body 210 includes a plurality of gas openings 207 extending between the pocket surface 213 and a second outer surface 208 of the support body 210. The second outer surface 208 opposes the outer surface 211. The plurality of gas openings 207 facilitate a gas flowing in the purge volume 138 to flow into and out of a space 209 between the recessed surface 212 and a backside face of the substrate 102. The gas in the space 209 can facilitate reducing or eliminating process gases flowing into the space and deposition on the backside face of the substrate 102. The gas in the space 209 can be used to center the substrate 102 relative to the support body 210. The gas can include a purge gas and/or a cleaning gas. Gravity can be used to guide the substrate 102 along the pocket surface 213 to position the substrate 102 and/or center the substrate 102 relative to the support body 210.

The pocket surface 213 has a surface roughness (Ra) that is less than 15 micro-inches. In one or more embodiments, the surface roughness (Ra) is within a range of 6 micro-inches to 12 micro-inches. The surface roughness (Ra) can be formed by, for example, polishing the pocket surface 213. In one or more embodiments, the polishing is a mechanical polishing. Other polishing techniques (such as chemical polishing or chemical-mechanical polishing) are contemplated. Other surface treatment techniques for forming the surface roughness (Ra) are contemplated.

The pocket surface 213 is tapered and has a taper angle A1 relative to the recessed surface 212. In one or more embodiments, the taper angle A1 is 45 degrees or more, such as 60 degrees or more. In one or more embodiments, the taper angle A1 is within a range of 45 degrees to 90 degrees, such as within a range of 70 degrees to 85 degrees. The taper angle A1 facilitates polishing the pocket surface 213, reduced or eliminated entry of process gases behind the substrate 102, reduced misalignment of the substrate 102 during processing, reduced or eliminated contact area between the substrate 102 and the support body 210, thermal uniformity, and increased deposition uniformity. The present disclosure contemplates that the pocket surface 213 can be arcuate.

The substrate support 106 includes a barrier 230 interfacing with the plurality of supports 215. The barrier 230 can function as a thermal barrier between the substrate 102 and the support body 210 such that thermal uniformity across the substrate 102, facilitating increased deposition uniformity across the substrate 102. The barrier 230 includes a barrier plate 231 and a plurality of barrier supports 235 protruding relative to a first side of the barrier plate 231. In one or more embodiments, each barrier support 235 of the plurality of barrier supports 235 contacts at least two of the plurality of supports 215 of the support body 210. In one or more embodiments, each barrier support 235 of the plurality of barrier supports 235 contacts three or more (such as four or more) of the plurality of supports 215 of the support body 210. The barrier 230 includes a plurality of second barrier supports 240 protruding relative to a second side of the barrier plate 231. The second barrier supports 240 support the substrate 102, such as during epitaxial deposition processing of the substrate 102. In one or more embodiments, each of the plurality of barrier supports 235 and each of the plurality of second barrier supports 240 is semi-ball shaped. In one or more embodiments, the support body 210 and the barrier 230 are each formed of silicon carbide (SiC) or graphite coated with SiC.

The recessed surface 212 has an outer radius OR1. The plurality of barrier supports 235 and the plurality of second barrier supports 240 are aligned with a radial position 236 that is a ratio of the outer radius OR1. In one or more embodiments, the ratio is within a range of 0.4 to 0.6, such as within a range of 0.45 to 0.55. In one or more embodiments, the ratio is 0.5. In one or more embodiments, the radial position 236 is aligned with geometric centers of the barrier supports 235 and the second barrier supports 240. The outer radius OR1 and the radial position 236 are considered relative to a geometric center 203 of the support body 210. The barrier supports 235 and the second barrier supports 240 are disposed at a radius R1 relative to the geometric center 203. The radius R1 is a ratio of a radius R2 of the substrate 102. In one or more embodiments, the radius R1 is a radius ratio of the radius R2 of the substrate 102, and the radius ratio is within a range of 0.4 to 0.6, such as within a range of 0.45 to 0.55. In one or more embodiments, the radius ratio is 0.5. In one or more embodiments, the radius R1 is within a range of 65 mm to 85 mm, such as 75 mm. Radial position 236 of the barrier supports 235, 240 can be aligned with portion(s) of the substrate 102 that remain substantially stationary during deformation due to processing, which facilitates uniformity and more consistently maintaining reduced or eliminated contact areas between the substrate 102 and the support body 210.

The barrier supports 235 can each include one or more outer arcuate surfaces that contact one or more outer arcuate surfaces of the supports 215. The one or more outer arcuate surfaces of the barrier supports 235 have a radius of curvature that is substantially equal to (such as within a difference of 10% or less relative to) a radius of curvature of the one or more outer arcuate surfaces of the supports 215. The second barrier supports 240 can each include one or more outer arcuate surfaces. The one or more outer arcuate surfaces of the second barrier supports 240 have a radius of curvature that is substantially equal to (such as within a difference of 10% or less relative to) the radius of curvature of the one or more outer arcuate surfaces of the barrier supports 235. Radii of curvature and the fusing facilitate reduced contact areas between the barrier 230 and the support body 210, which facilitates increased thermal and deposition uniformity.

In the implementation shown in FIG. 2, the substrate 102 has an initial deformation (e.g., entering the processing chamber 100 as pre-bowed) prior to processing. The substrate 102 can become deformed (e.g., bowed) during processing, and the substrate 102 can deform in the opposite direction into a subsequent deformation, as shown by a deformed position 202 shown in ghost in FIG. 2. For example, the substrate 102 can deform from a concave orientation and into a convex orientation. The deformation can be caused, for example, by attempted expansion of one or more film layers that are epitaxially deposited on the substrate 102 during processing. The support body 210 and the barrier 230 facilitate reliably supporting the substrate 102 during deformation of the substrate 102 (e.g., during processing), which facilitates reduced misalignment of the substrate 102, reduced defects, increased throughput, enhanced device performance, and enhanced deposition uniformity (such as center-to-edge uniformity).

Fused sections 238 can fuse the barrier supports 235 of the barrier 230 to the supports 215 of the support body 210. For example, particles can form between the barrier supports 235 and the supports 215 to form the fused sections 238. As another example, portions of the barrier supports 235 and/or the supports 215 can melt to form the fused sections 238.

The supports 215, the barrier supports 235, the second barrier supports 240, and the fused sections 238 facilitate spreading out heat and thermal uniformity (and deposition uniformity).

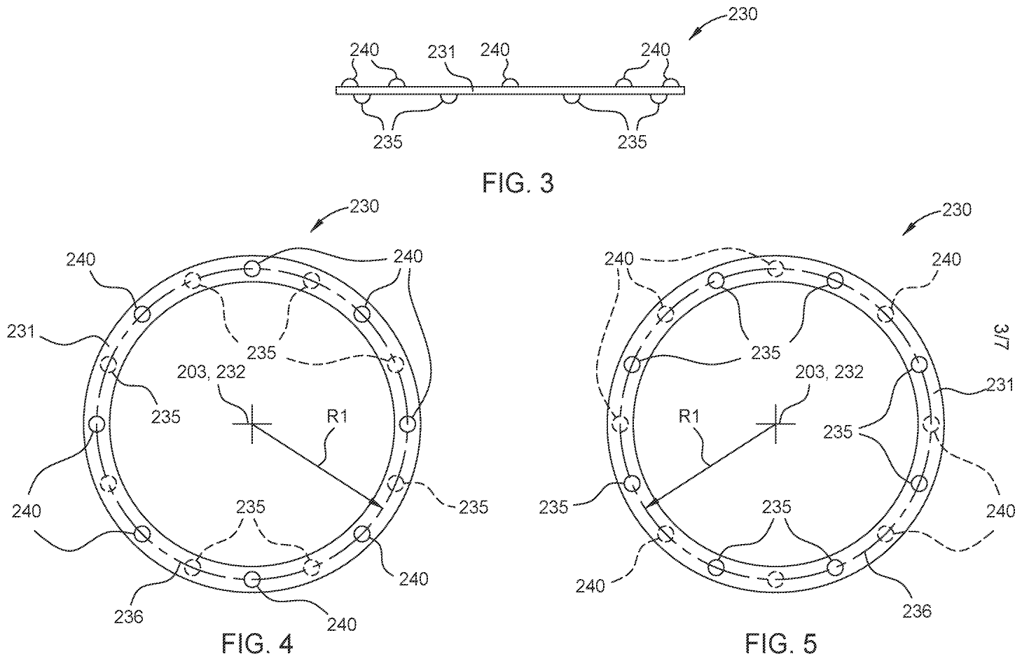

FIG. 3 is a schematic side view of the barrier 230 shown in FIG. 2, according to one implementation.

FIG. 4 is a schematic top view of the barrier 230 shown in FIGS. 2-3, according to one implementation.

FIG. 5 is a schematic bottom view of the barrier 230 shown in FIGS. 2-4, according to one implementation.

The barrier plate 231 is a ring. The plurality of second barrier supports 240 are circumferentially offset from the plurality of barrier supports 235 such that the second barrier supports 240 are misaligned from the barrier supports 235 in radial directions extending linearly outwardly relative to a geometric center 232 of the barrier plate 231 (in a manner similar to that shown for the radius R1). In the implementation shown, the barrier 230 includes eight barrier supports 235 and eight second barrier supports 240. The present disclosure contemplates that different numbers (such as twelve) may be used for the barrier supports 235 and the second barrier supports 240.

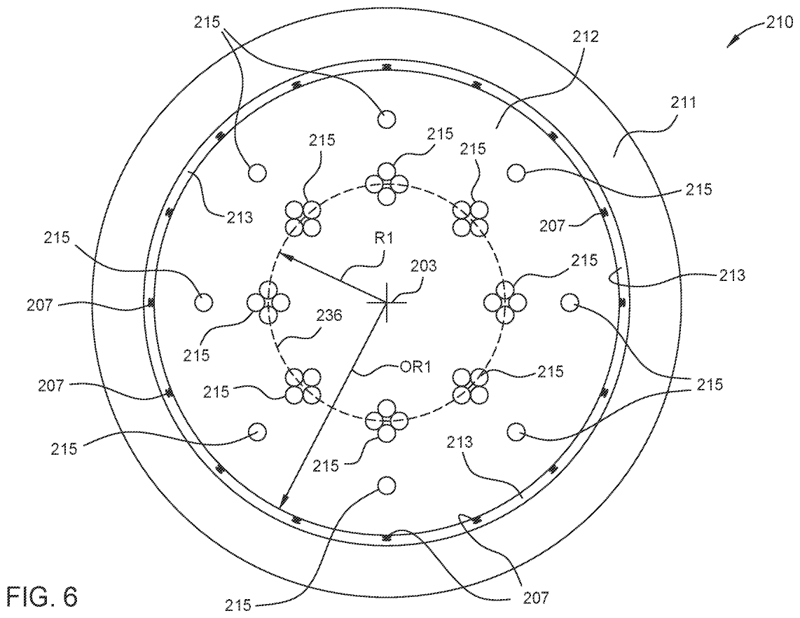

FIG. 6 is a schematic top view of the support body 210 shown in FIG. 2, according to one implementation.

Some of the supports 215 of the support body 210 are not shown in FIG. 6. The present disclosure contemplates that the number of supports 215 can differ from what is shown in the figures described herein. The present disclosure contemplates that the positions of the supports 215 can differ from what is shown in the figures described herein. As an example, at least some of the supports 215 shown in FIG. 6 can be omitted. As another example, supports 215 can be disposed circumferentially between the supports 215 shown in FIG. 6, supports 215 can be disposed radially inward of the supports 215 shown in FIG. 6, and/or supports 215 can be disposed radially outward of the supports 215 shown in FIG. 6.

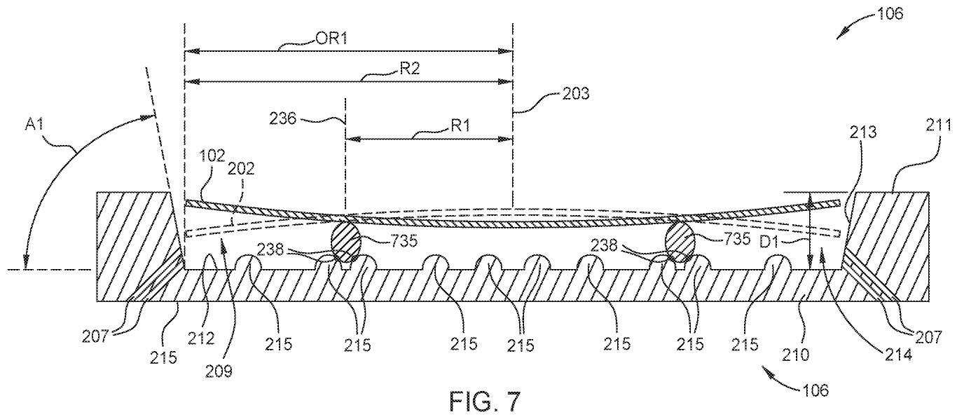

FIG. 7 is a schematic side cross-sectional view of a substrate support 706, according to one implementation. The substrate support 706 can be used at least partially in place of the substrate support 106 shown in FIG. 1. The substrate support 706 is similar to the substrate support 106 shown in FIGS. 1 and 2, and includes one or more aspects, features, components, operations, and/or properties thereof.

In the implementation shown in FIG. 7, a barrier includes a plurality of barrier supports 735. The plurality of barrier supports 735 are ball shaped (such as spherical in shape or ovular in shape). The present disclosure contemplates that a barrier plate can be omitted such that the barrier supports 735 can be moved into position individually (e.g., prior to fusing).

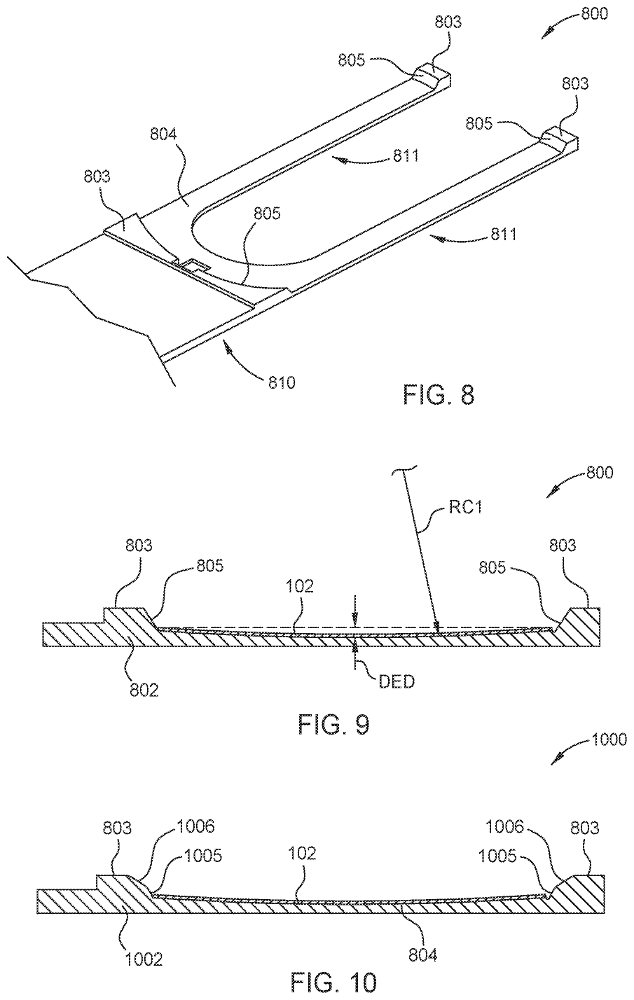

FIG. 8 is a schematic perspective view of a transfer apparatus 800, according to one implementation.

FIG. 9 is a schematic side cross-sectional view of the transfer apparatus 800 shown in FIG. 8, according to one implementation. The transfer apparatus 800 is for moving a substrate (such as the substrate 102) in relation to semiconductor manufacturing. For example, the transfer apparatus 800 can move the substrate into and out of the processing chamber 100 through the transfer door 137.

The transfer apparatus 800 includes a transfer body 802. The transfer body 802 includes one or more outer surfaces 803, an arcuate recessed surface 804 that is recessed relative to the one or more outer surfaces 803, and one or more pocket surfaces 805 between the one or more outer surfaces 803 and the arcuate recessed surface 804. In one or more embodiments, the transfer body 802 is a blade, for example a robot blade that attaches to a transfer robot in a transfer chamber. In one or more embodiments, the transfer body 802 includes a wrist 810 and a plurality of arms 811. In one or more embodiments, the transfer body 802 is formed of quartz. The arcuate recessed surface 804 can span one or more (such as all) of the plurality of arms 811. The one or more pocket surfaces 805 can be tapered or arcuate. The one or more pocket surfaces 805 can have a taper angle that is the same as or less than the taper angle A1 described above.

The one or more pocket surfaces 805 are treated (e.g., polished) to have the surface roughness (Ra) described above in relation to the pocket surface 213 described above. The arcuate recessed surface 804 is semi-ball shaped and has a radius of curvature RC1 that is within a range of 10.5 meters to 12.0 meters. In one or more embodiments, the radius of curvature RC1 is about 11.25 meters (such as 11.2505 meters).

Other values are contemplated for the radius of curvature RC1. In one or more embodiments, the radius of curvature RC1 is determined and set according to the following Equation 1 (where R is the radius of curvature; DED is a deformation distance; and SR is a radius of the substrate being transferred):

$${R}^{2} = {( R - D E D )}^{2} + S {R}^{2} \qquad ( Equation 1 )$$

In one or more embodiments, the deformation distance DED is about 1 mm and the radius SR is about 150 mm. The deformation distance DED can be a maximum deformation of the substrate, which can be a distance between a vertical position of the outer edge of the substrate and a vertical position of a center of the substrate (as shown in FIG. 9).

Gravity can be used to guide the substrate 102 along the one or more pocket surfaces 805 and/or the arcuate recessed surface 804 to position the substrate 102 and/or center the substrate 102 relative to the transfer body 802.

FIG. 10 is a schematic side cross-sectional view of a transfer apparatus 1000, according to one implementation.

The transfer apparatus 1000 can be used at least partially in place of the transfer apparatus 800 shown in FIGS. 8 and 9. The transfer apparatus 1000 is similar to the transfer apparatus 800 shown in FIGS. 8 and 9, and includes one or more aspects, features, components, operations, and/or properties thereof.

A transfer body 1002 includes one or pocket surfaces 1005 and one or more second pocket surfaces 1006 between the one or more pocket surfaces 1005 and the one or more outer surfaces 803. The one or more pocket surfaces 1005 and the one or more second pocket surfaces 1006 can be tapered or arcuate.

The one or more pocket surfaces 1005 can have a taper angle that is the same as or greater than the taper angle A1 described above. The one or more second pocket surfaces 1006 can have a taper angle that is the same as or greater than the taper angle A1 described above. The one or more second pocket surfaces 1006 can have a taper angle that is less than the taper angle of the one or more pocket surfaces 1005.

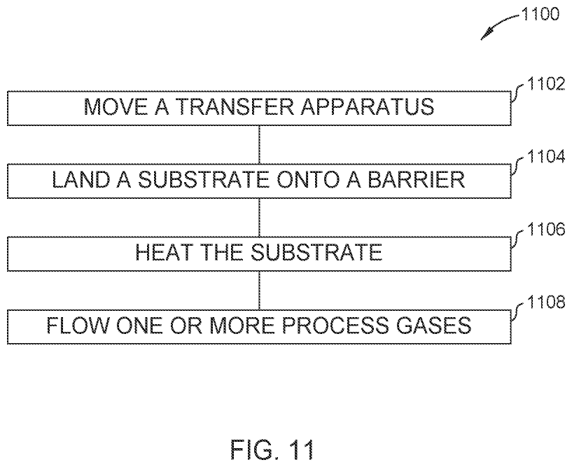

FIG. 11 is a schematic block diagram view of a method 1100 of processing a substrate for semiconductor manufacturing, according to one implementation.

Operation 1102 includes moving a transfer apparatus into the processing volume to move a substrate into a processing volume of a processing chamber. The transfer apparatus is a transfer apparatus discussed herein.

Operation 1104 includes landing the substrate onto a barrier that is supported on a support body.

Operation 1106 includes heating the substrate positioned in the processing volume of the processing chamber while the substrate is positioned on the barrier.

Operation 1108 includes flowing one or more process gases over the substrate to form one or more layers on the substrate while the substrate is positioned on the barrier.

Benefits of the present disclosure include accounting for substrate deformations; modularity in process parameters (such as processing temperatures); reliably supporting substrates during deformation of the substrates (e.g., during processing); more consistent contact areas between the substrates and other components; reduced or eliminated misalignment of the substrates; reduced or eliminated substrate defects; increased throughput; enhanced device performance; enhanced thermal uniformity; enhanced thermal and deposition adjustability; and enhanced deposition uniformity (such as center-to-edge uniformity).

It is contemplated that one or more aspects disclosed herein may be combined. As an example, one or more aspects, features, components, operations, and/or properties of the various implementations of the processing chamber 100, the controller 120, the substrate support 106, the support body 210, the barrier 230, the substrate support 706, the barrier shown in FIG. 7, the transfer apparatus 800, the transfer apparatus 1000, and/or the method 1100 may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof, and the scope thereof is determined by the claims that follow.

What is claimed is:

1. A substrate support applicable for use in semiconductor manufacturing operations, the substrate support comprising:
a support body, the support body comprising:
an outer surface,
a recessed surface that is recessed relative to the outer surface,
a pocket surface between the outer surface and the recessed surface, the recessed surface and the pocket surface at least partially defining a pocket of the support body, and
a plurality of supports protruding relative to the recessed surface; and
a barrier interfacing with the plurality of supports, the barrier comprising a plurality of barrier supports.

2. The substrate support of claim 1, wherein a depth of the pocket is less than 1.0 mm.

3. The substrate support of claim 1, wherein the pocket surface is tapered and has a taper angle relative to the recessed surface, and the taper angle is 45 degrees or more.

4. The substrate support of claim 3, wherein the pocket surface has a surface roughness that is less than 15 micro-inches.

5. The substrate support of claim 1, wherein each of the plurality of barrier supports is ball shaped.

6. The substrate support of claim 1, wherein the barrier further comprises a barrier plate, the plurality of barrier supports protrude relative to a first side of the barrier plate, and each barrier support of the plurality of barrier supports contacts at least two of the plurality of supports.

7. The substrate support of claim 6, wherein the barrier further comprises a plurality of second barrier supports protruding relative to a second side of the barrier plate.

8. The substrate support of claim 7, wherein each of the plurality of supports, each of the plurality of barrier supports, and each of the plurality of second barrier supports is semi-ball shaped.

9. The substrate support of claim 7, wherein the barrier plate is a ring, and the plurality of second barrier supports are circumferentially offset from the plurality of barrier supports.

10. The substrate support of claim 1, wherein the support body further comprises a plurality of gas openings extending between the pocket surface and a second outer surface of the support body, the second outer surface opposing the outer surface.

11. The substrate support of claim 1, wherein the support body and the barrier are each formed of silicon carbide (SiC) or graphite coated with SiC.

12. The substrate support of claim 1, wherein the recessed surface has an outer radius, and the plurality of barrier supports are aligned with a radial position that is a ratio of the outer radius, and the ratio is within a range of 0.4 to 0.6.

13. A processing chamber applicable for use in semiconductor manufacturing, comprising:
a window at least partially defining a processing volume;
a plurality of heat sources configured to heat the processing volume; and
a substrate support disposed in the processing volume, the substrate support comprising:
a support body, the support body comprising:
an outer surface,
a recessed surface that is recessed relative to the outer surface,
a pocket surface between the outer surface and the recessed surface, and
a plurality of supports protruding relative to the recessed surface, and
a barrier interfacing with the plurality of supports, the barrier comprising a plurality of barrier supports.

14. The substrate support of claim 13, wherein the barrier further comprises a barrier plate, the plurality of barrier supports protrude relative to a first side of the barrier plate, and each barrier support of the plurality of barrier supports contacts at least two of the plurality of supports.

15. The processing chamber of claim 13, wherein the recessed surface has an outer radius, and the plurality of barrier supports are aligned with a radial position that is a ratio of the outer radius, and the ratio is within a range of 0.4 to 0.6.

16. A transfer apparatus for moving a substrate in relation to semiconductor manufacturing, the transfer apparatus comprising:
a transfer body, the transfer body comprising:
an outer surface,
an arcuate recessed surface that is recessed relative to the outer surface,
a pocket surface between the outer surface and the arcuate recessed surface.

17. The transfer apparatus of claim 16, wherein the arcuate recessed surface is semi-ball shaped and has a radius of curvature that is within a range of 10.5 meters to 12.0 meters.

18. The transfer apparatus of claim 17, wherein the transfer body is formed of quartz.

19. The transfer apparatus of claim 16, wherein the transfer body is a blade comprising a wrist and a plurality of arms.

20. The transfer apparatus of claim 16, wherein the transfer body further comprises a second pocket surface between the pocket surface and the outer surface.
